(19) United States
(12) Patent Application Publication
(10) Pub. No.: US 2026/0239936 A1
(43) Pub. Date: Aug. 13, 2026

(54) REDUCING TENSILE FILM CRACKING

(71) Applicant: Lam Research Corporation, Fremont, CA (US)

(72) Inventors: Michael Anthony Chan, Beaverton, OR (US); Soumana Hamma, Tigard, OR (US)

(21) Appl. No.: 19/153,053

(22) PCT Filed: Jan. 30, 2024
(86) PCT No.: PCT/US2024/013598

§ 371 Date: Aug. 1, 2025

Related U.S. Application Data
(60) Provisional application No. 63/483,256, filed on Feb. 3, 2023.

(51) Int. Cl. H10P 95/60; H10P 14/692; H10P 14/694

(52) U.S. Cl. CPC H10P 95/60; H10P 14/69215; H10P 14/6927; H10P 14/69433

(57) ABSTRACT

Provided are methods and structures for keeping the integrity of layers deposited on a semiconductor wafer. Deposition of a multilayer backside layer stack may reduce incidents of cracking in a backside layer. Each of the backside layers may be deposited by a backside deposition apparatus. a method of processing a substrate during fabrication of an electronic device, the method comprising depositing one or more frontside layers on a frontside of the substrate, wherein the one or more frontside layers induce a bow in the substrate; depositing a first bulk backside layer on a backside of the substrate, wherein the first bulk backside layer reduces the bow in the substrate; depositing a crack arresting backside layer over the first backside layer; and depositing a second bulk backside layer over the second backside layer, wherein the second bulk backside layer further reduces the bow in the substrate.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

In semiconductor processing, it may be desired that a wafer remains substantially flat. However, during normal operations, a wafer may experience wafer bow. The wafer bow may cause issues such as improper clamping by an electrostatic chuck, inability to be held by a wafer handler, pattern transfer issues during photolithography issues, and others. Processes have been developed to manage wafer bow by keeping the wafer flat within process tolerances. One process includes depositing a film on the backside of the wafer to counteract any stress that may be causing the wafer to bow. While this stress from the deposited backside film may keep the wafer substantially flat, if the backside film becomes too thick—as may be necessitated for wafers with large bow—the film can crack and potentially damage the wafer and/or the handling apparatus.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

This summary is provided to introduce some concepts in simplified form that are further described below in the Detailed Description. This summary is not intended to identify key features or essential features of the claimed subject matter.

Some aspects of this disclosure pertain to methods of processing a substrate during fabrication of an electronic device. Such methods may be characterized by the following operations: (a) depositing one or more frontside layers on a frontside of the substrate, where the one or more frontside layers induce a bow in the substrate; (b) depositing a first bulk backside layer on a backside of the substrate, where the first bulk backside layer reduces the bow in the substrate; (c) depositing a crack arresting backside layer over the first backside layer; and (d) depositing a second bulk backside layer over the second backside layer, where the second bulk backside layer further reduces the bow in the substrate.

In some embodiments, the first bulk backside layer, the crack arresting backside layer, and the second bulk backside layer collectively comprise a backside stack, and wherein the backside stack has a thickness of about 2 to 15 μm. In some embodiments, the first bulk backside layer and the second bulk backside layers each have thicknesses about 3 μm or less.

In certain embodiments, the first bulk backside layer comprises a silicon nitride. In some cases, the first bulk backside layer has an intrinsic internal stress magnitude of about 100 MPa to 1000 MPa.

In certain embodiments, the crack arresting backside layer comprises a silicon nitride, a silicon oxide, a silicon oxynitride, or any combination thereof. In some cases, the crack arresting backside layer has a density of about 2 to 3.5 g/cm. In some cases, the crack arresting backside layer has a thickness of about 2 μm or less. In some implementations, the crack arresting backside layer has an elastic modulus of about 180 GPa to 250 GPa.

In certain embodiments, the bow of the substrate is about 300 μm or more. In certain embodiments, at least one of the one or more frontside layers comprises a hardmask. In certain embodiments, the one or more frontside layers comprise a stack of about 100 or more alternating layers. In some such cases, the stack comprises alternating oxide layers and nitride or polysilicon layers. In certain embodiments, the one or more frontside layers has a first type of internal stress and wherein the first bulk backside layer has the first type of internal stress.

Any combination of the above features may implemented be together in method aspects of this disclosure.

Certain aspects of this disclosure pertain to apparatuses for semiconductor processing, which apparatus may be characterized by the following features: (a) a process chamber; (b) a substrate support within the process chamber; (c) a showerhead; (d) a gas source fluidically connected to the showerhead; and (e) a controller configured to cause: (i) receiving a substrate comprising one or more frontside layers that cause bow in the substrate; (ii) depositing a first bulk backside layer on a backside of the substrate, which first backside layer reduces bow in the substrate; (iii) depositing a crack arresting backside layer over the first backside layer; and (iv) depositing a second bulk backside layer over the second backside layer, where the second bulk backside layer further reduces the bow in the substrate.

In certain embodiments, the bow in the substrate is about 300 μm or more. In certain embodiments, at least one of the one or more frontside layers is a hardmask. In certain embodiments, the one or more frontside layers comprise a stack of about 100 or more alternating layers.

In some implementations, the controller is configured to cause the first bulk backside layer, the crack arresting backside layer, and the second bulk backside layer (collectively comprising a backside stack) to have a thickness of about 2 to 15 μm. In certain embodiments, the first bulk backside layer and the second bulk backside layers each have thicknesses about 3 μm or less.

In certain embodiments, the first bulk backside layer comprises a silicon nitride. In certain embodiments, the first bulk backside layer has an intrinsic internal stress of about −500 MPa to 500 MPa.

In certain embodiments, the crack arresting backside layer has a density of about 2 to 3.5 g/cm. In some cases, the crack arresting backside layer has a thickness of about 2 μm or less. In some implementations, the crack arresting backside layer has an elastic modulus of about 180 GPa to 250 GPa. In some implementations, the crack arresting backside layer comprises a silicon nitride, a silicon oxide, a silicon oxynitride, or any combination thereof.

Any combination of the above features may be implemented together in apparatus aspects of this disclosure.

In the above-described aspects of the disclosure, any combination of the one or more dependent features may be implemented together with, or apart from, one another when used with the primary system or method aspect. Additional aspects and features of the disclosure will be presented below, sometimes with reference to associated drawings.

### BRIEF DESCRIPTION OF THE DRAWINGS

FIGS. 1A and 1B show examples of unbowed and bowed semiconductor wafers on an electrostatic chuck.

FIG. 2A shows example profile views of bow of a wafer and the impacts of backside layer and the cracking that can be result from high bow cases

FIG. 2B shows example profile views of bow of a wafer, similar to the views in FIG. 2A, but the backside layer structure includes a crack arresting layer that prevents the cracking shown in FIG. 2A.

FIG. 3 is a process flow diagram illustrating certain operation in semiconductor wafer processing.

FIG. 4 is a process flow diagram illustrating certain operation in semiconductor wafer processing.

FIG. 5 shows an example cross section of a semiconductor wafer during semiconductor processing according to various embodiments.

FIGS. 6A and 6B show a block diagram of an example substrate processing system.

FIG. 7A shows an example cross section of an edge of a shower-pedestal.

FIG. 7B shows a top view of an example carrier ring.

FIG. 8 shows a schematic of an example process system that may be used to perform the methods described herein.

### DETAILED DESCRIPTION

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, 300 mm, or 450 mm. Examples of wafer materials include silicon (Si), gallium arsenide (GaAs), and silicon germanium (SiGe). Besides semiconductor wafers, other workpieces that may take advantage of the disclosed embodiments include various articles such as printed circuit boards, magnetic recording media, magnetic recording sensors, mirrors, optical elements, display devices or components such as backplanes for pixelated display devices, flat panel displays, micro-mechanical devices and the like. The workpiece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment performs one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

“Wafer bow” as used herein may refer to a deformation of a wafer. The deformation may have radial and/or azimuthal components. Examples of types of wafer bow include dome shapes, dish shapes, and potato chip shapes. Wafer bow may occur during fabrication, for example, as a result of stress to the wafer during deposition of materials on an active surface of a wafer substrate. Wafer bow may occur during various types of fabrication, such as when large stacks of materials are deposited. Wafer bow may cause complications in subsequent processing steps. For example, the wafer may fail to chuck correctly if an amount of bowing is too large. Moreover, some processing steps (e.g., photolithography) may produce poor results if performed on a wafer that is excessively bowed.

Wafer bow may be measured as a deviation of the mean or median distance of the surface of the wafer to a reference plane. The point of the median surface of the wafer may be the center point (e.g., in the case of concave or domed bowing), or an edge point of the wafer and/or an average edge point of the wafer (e.g., in the case of warping or convex bowing).

### Bowed Wafers

Semiconductor device fabrication often involves deposition of a stack of layers on a wafer substrate. Typically, most deposition and other processing to form the devices occurs on one side of the substrate, often referred to as the front face or frontside of a wafer. As the deposited layers build up, they can introduce stress in the wafer. A large net tensile or compressive stress can cause the wafer to bow, which is undesirable.

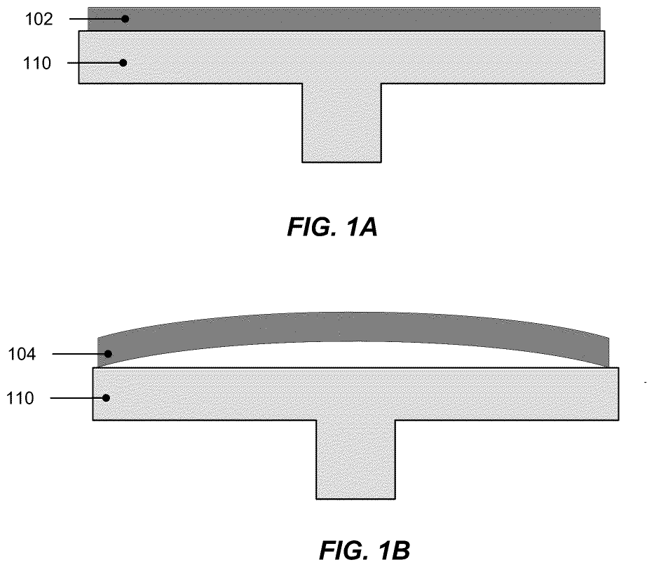

Bowing is especially likely to occur where large stacks of materials are deposited, for example, in the context of 3D-NAND devices, or where a thick front side layer is deposited. Where bowing is significant, it can deleteriously affect subsequent processing steps. For instance, the wafer may fail to chuck correctly if the bowing is too great. FIGS. 1A and 1B show a wafer on an electrostatic chuck. FIG. 1A shows a wafer 102 on an electrostatic chuck 110. When the wafer 102 is substantially flat for purposes of a particular process operation, e.g., having a bow of about 100μm or less, the wafer may be properly clamped, securing the wafer for subsequent processing steps. FIG. 1B shows a bowed wafer 104 on the electrostatic chuck 110. When the bow is significant, the wafer may fail to secure properly on the electrostatic chuck. Wafer bow may cause other problems. For example, certain processing steps (e.g., photolithography) are very precise and produce poor results if the wafer is not substantially flat. The problem may be manifest as lithography defocus.

One example stack that may cause these problems is a stack having alternating layers of oxide and nitride (e.g., silicon oxide/silicon nitride/silicon oxide/silicon nitride, etc.). Another example of a type of stack likely to cause bowing includes alternating layers of oxide and polysilicon (e.g., silicon oxide/polysilicon/silicon oxide/polysilicon, etc.). Other examples of stack materials that may be problematic include, but are not limited to, tungsten and titanium nitride.

The materials in the stacks may be deposited through chemical vapor deposition (CVD) techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc. These examples are not intended to be limiting. Certain disclosed embodiments may be useful whenever wafer stress and/or bowing are induced due to material present on the frontside of the wafer.

The frontside stacks may be deposited to any number of layers and thicknesses. In an example, the stack includes about 20 or more layers, and has a total thickness of about 2 μm to about 4 μm. However, in some cases, multiple-layer stacks have about one hundred or more layers. In some embodiments, multiple-layer stacks may have about five hundred or more layers. In some embodiments, the multiple-layer stacks may have about one thousand or more layers. Such stacks may have a thickness of about 4 μm to 12 μm, for example.

The stress induced in the wafer by the stack or other frontside deposition may be about −500 MPa to about +500 MPa. In some embodiments, the resulting in a bow is about 150 μm or greater, e.g., about 300 μm and above, about 400 μm and above, or about 200 μm to about 400 μm (for a 300 mm wafer).

Another cause of wafer bow may be frontside processing which uses thick hardmasks with limited etch selectivity. In these embodiments, at least one of the one or more frontside layers is a hardmask. The thick hardmasks may have an internal stress similar to those described above, e.g., have a magnitude of 0 MPa to about 500 MPa. The stress caused by the hardmask may be tensile stress or compressive. The thick hardmasks may cause wafers to have a significant wafer bow, e.g., about 150 μm or more.

Various techniques have been devised for combatting bowing. When bowing is more severe, deposition processes may be tuned to reduce or counteract internal stresses in deposited layers. However, any such tuning should not interfere with process requirements for fabricating devices. One commonly used technique to counteract bowing deposits a film on the back side of the wafer.

Backside deposition may form a high-stress film. If the backside layer has the same type of internal stress (tensile or compressive) and of comparable magnitude to the internal stress created on the frontside, the backside film effectively counteracts and reduces the bow.

Examples of backside films used to counteract bow include the following: amorphous silicon, silicon oxide, silicon nitride, and silicon oxynitride. Current backside films have high internal stress and can mitigate the stresses imparted on the wafer from the frontside layers to reduce or eliminate the wafer bow. Generally, backside layers are made of films with high stress.

Until relatively recently, the backside film thickness remained relatively thin (e.g., <2 μm) because the bow caused by depositing material on the frontside was relatively modest. Thus, downstream processes at previous technology nodes did not normally experience issues addressed by embodiments herein. However, modern IC fabrication techniques may produce substrates having frontside layers that produce much more severe wafer bow compared to previous nodes. For example, some modern processes use thick hardmask layers in operations where the etch selectivity between the hardmask and etched material is limited, yet deep trenches or vias are etched. In another example, frontside stacks have increased the number of layers. For example, in previous nodes stacks may have been about 32 to about 72 layers. Now, stacks may have hundreds or even thousands of layers, increasing the thickness of the frontside layer and the internal stress. Typically wafer bow compensation is achieved by depositing a single backside layer. Due to the increasing magnitude of wafer bow, thicker backside films must be deposited to compensate for wafer bow. This has caused certain issues. Due to large internal forces occurring within thick backside layers, the layers may spontaneously form film cracks. For many film materials (e.g., tensile silicon nitride films), cracks are observed in films of thicknesses necessary to compensate for bow values above a critical bow limit. These bow limits are commonly known as the “bow cracking limit” or “cracking margin.”

If a crack does form, it may create separations large enough to provide a pathway for contaminants to directly contact the backside of the wafer, potentially damaging it. For example, chemical wet etchants, which are often used to remove backside films, may penetrate through a film crack in a backside film leading to a non-uniform etch or wafer etching, which can cause particles issues such as film flaking. Furthermore, these film cracks may be so severe that they cause the wafer itself to crack, in some cases to a depth twice as great as the film thickness.

To avoid backside film cracking, wafer bowing may be limited to an amount well below the bow cracking limit of the film. This means that some wafer integration procedures are conducted in stages, with an operation that would normally be conducted in a single step being divided into a series of steps, each introducing a relatively small bow that is compensated by a commensurately thin backside layer. This adds complexity to device manufacturing and decreases overall throughput.

### Multilayer Backside Bow Compensation

Disclosed herein are methods, systems, and techniques for maintaining the integrity of backside layers and wafer. This reduces the potential of damage to the wafer and reduces the risk of a wafer handling problem during subsequent wafer processing.

In certain embodiments, the wafer may have a second backside layer sandwiched between two bulk backside layers. By choosing properties of the second backside layer such as mechanical toughness and/or other mechanical properties, the second backside layer may reduce the probability of cracks forming on deposited layers. The second backside layer is sometimes referred to as a “crack arresting layer” herein. A crack arresting layer is a backside layer that may be formed between two bulk backside layers. The bulk backside layers have an internal stress that is the same type as the net stress produced by the front side layer(s). In a stack comprising a crack arresting layer between two bulk layers, the bulk layers may primarily serve to compensate wafer bow while the crack arresting layer provides mechanical strength to prevent one or both of the bulk layers from cracking. The crack arresting layer thereby reduces the probability of cracking of the bulk layers.

The backside stack structure may use multiple film layers to increase the bow cracking margin without sacrificing the cost effectiveness or other beneficial properties of the individual films. It has been found that a crack arresting layer can extend the bow cracking limit of a bulk film. In various embodiments, the bulk film used for the top and bottom layers of a film stack makes up most of the thickness of the stack. A middle, crack arresting layer may contribute only a small proportion of the total stack thickness.

In some cases, the crack arresting layer is a denser and/or tougher layer than the bulk layer(s), and as such it may aid in strengthening the overall backside layer. By employing such films, the bow cracking limit can be extended without sacrificing the cost effectiveness or other beneficial properties of the bulk film. By avoiding film cracking, the previous mentioned contamination and mechanical integrity issues can be avoided, while effectively compensating for high values of wafer bow. Additionally, because the backside stack can be deposited in a single, continuous operation, the overall process scheme condenses frontside integration steps and reduces the number of back side deposition operations.

In some cases, a backside layer includes multiple crack arresting layers, optionally with more bulk layers. Such structures may allow a process to accept an even higher total bow compared to the case where only a single crack arresting layer is used.

The bulk and crack arresting layers may be deposited by any of various techniques including PECVD, PVD, CVD, ALD, epitaxial growth, and PEALD. Films generated by any of these techniques can spontaneously crack above their critical thicknesses. The disclosed sandwich stack can help achieve higher bows and thicknesses with films deposited by any of these, and other, techniques.

During wafer processing, a wafer may be subjected to a thermal cycle. The thermal cycle subjects the wafer to an elevated temperature. It may be caused by any of various process operations. The thermal cycle may induce a bow shift of the wafer. Generally, a wafer with a large bow may experience a relatively large bow shift. Large bow shifts have an increased chance of cracking layers deposited on the wafer, e.g., the backside layer. One example of a thermal cycle is annealing of the wafer. Another example of a thermal cycle is depositing a material such as a hardmask on the frontside of the wafer. For example, deposition make cause a thermal cycle when it takes place at temperatures above about 650° C. or above about 850° C. In another example, thermal annealing may subject the wafer to a thermal cycle, for example at temperatures up to about 1100° C. A backside film stack including a crack arresting layer as disclosed herein may reduce the likelihood of cracking during a thermal cycle.

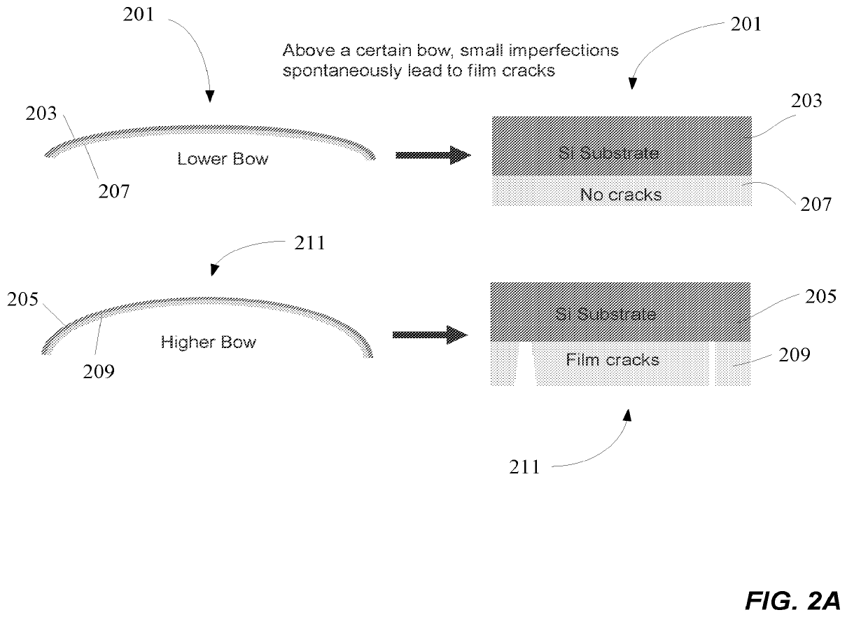

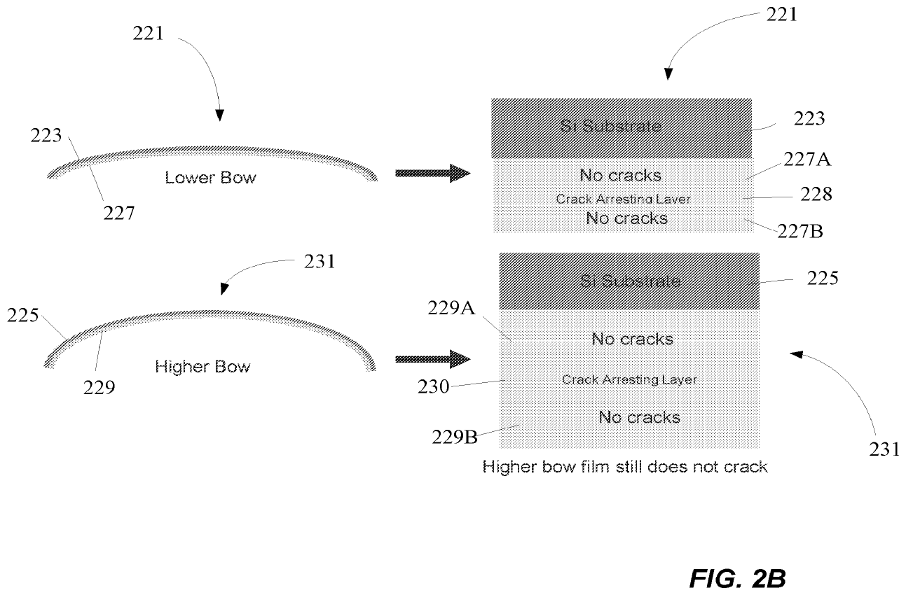

FIG. 2A schematically depicts the issue of backside film cracking. As shown in an upper panel, a wafer 201 with relatively modest bow can be flattened by using a single backside layer, while in the lower panel, a wafer 211 with relatively higher bow exhibits backside film cracking. More specifically, wafer 201 includes a silicon substrate portion 203, which includes one or more front side bow-inducing layers (not shown), and a backside, bow-compensating, layer 207. As shown in the upper right panel, backside layer 207 can flatten wafer 201 without exhibiting cracking. However, wafer 211, which includes a silicon substrate 205 with one or more bow-inducing front side layers (not shown), and a backside, bow-compensating, layer 209, exhibits significantly higher bow and therefore requires a thicker backside layer. Therefore, while backside layer 209 may substantially flatten wafer 211, as illustrated in the bottom right panel, it does so while risking cracking as shown in layer 209.

FIG. 2B illustrates how this cracking problem may be ameliorated or mitigated by using a crack arresting layer interposed between two bulk layers in a backside layer. As illustrated, a wafer 221 includes a silicon substrate 223 and a backside layer 227 stack and has a relatively modest bow. In contrast, a wafer 231 includes a silicon substrate layer 225 and a backside, bow-compensating layer 229 stack, and exhibits a significantly greater bow. Generally, wafers 221 and 231 correspond to wafers 201 and 211 from FIG. 2A. However, backside layer stacks 227 and 229 include an intermediate crack arresting layer, which is not present in the backside layers 207 and 209. Therefore, even wafer 231, which exhibits a very significant bow, does not exhibit cracking when a thick backside layer is deposited to flatten wafer 231. And, while crack arresting layer may not be critical to the integrity of a low bow wafers such as wafer 221, it can be incorporated in the backside layer stack without introducing significant issues.

As illustrated in FIG. 2B, wafer 221 includes a backside layer stack comprising bulk layers 227A and 227B sandwiching a crack arresting layer 228. Similarly, wafer 231 includes a backside layer stack including thick block backside layers 229A and 229B sandwiching a crack arresting layer 230.

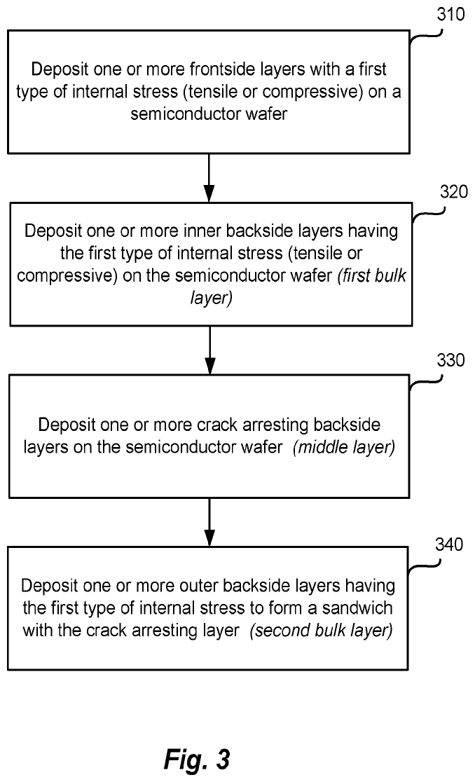

FIG. 3 shows a first example process using deposition of a backside layer structure including two or more bulk layers and a crack arresting layer. The process of FIG. 3 starts with depositing one or more frontside layers having a first type of internal stress (tensile or compressive) on a wafer in an operation 310. The internal stress from the frontside layer causes the wafer to bow. In some embodiments, the wafer bow is about 300 μm or more, e.g., about 400 μm or more.

Once a frontside layer is deposited onto the wafer, a first backside layer having an internal stress of the first type is deposited onto the wafer in an operation 320. In other words, the internal stress of the backside layer is the same type of internal stress of the frontside layer deposited in operation 310. For example, if the frontside layer deposited in operation 310 has a tensile internal stress, then the first backside layer deposited also has a tensile internal stress. In another example, if the frontside layer deposited in operation 310 has a compressive internal stress, then the first backside layer deposited also has a compressive internal stress. In some embodiments, the magnitude of the internal stress of the deposited first backside layer may be less than the magnitude of the internal stress of the deposited frontside layer; i.e., the first backside layer does not fully compensate the bow induced by the frontside layer(s). In some embodiments, the first backside layer reduces the bow of the wafer to about 200 μm or less. In some embodiments, the wafer may be substantially flat, i.e., the wafer has a bow of about 150 μm or less. Because the wafer may be processed to form a backside layer stack and because the first backside layer is forms the portion of the stack closest to the substrate, the first backside layer is sometimes referred to as an “inner” backside layer. Further because the inner backside layer, optionally along with a subsequently deposited outer backside layer, confirms most of the bow compensation and comprises most of the thickness of the backside layer stack, the inner backside layer and the outer backside layer are sometimes referred to as “bulk” layers.

The first backside layer may be deposited using CVD, PECVD, ALD, epitaxy, PVD, or other deposition process. The first backside layer may be deposited using a special purpose backside deposition apparatus. In some embodiments, the wafer switches chambers between operation 310 and operation 320. The backside deposition apparatus may be a different deposition apparatus then the apparatus used to deposit the one or more frontside layers.

In an operation 330, a second backside layer, or crack arresting backside layer, is deposited on the first/inner backside layer. The second backside layer may have a type of internal stress, which is neutral or the same or different than the first type of internal stress in the frontside layer and the first backside layer. For example, if the first type of stress is a tensile stress, the second type of stress is a compressive stress. In one example, both the frontside layer and the first backside layer have a tensile internal stress and the second backside layer has a compressive internal stress. In another example, the frontside layer as well as the first and second backside layers all have tensile stress. The magnitude of the bow compensated by the second backside layer may be less than the magnitude of the bow compensated by the first backside layer, e.g., about 50% or less, about 30% or less, about 20% or less, or about 10% or less.

The second (crack arresting) backside layer formed in operation 330 may be deposited in the same apparatus used to deposit the first backside layer in operation 320.

In an operation 340, the process deposits a third backside layer on the second, crack arresting, backside layer. This third backside layer is sometimes referred to as an outer backside layer. In some embodiments, it has substantially the same physical properties as the first, inner, backside layer. In some cases, the outer backside layer has substantially the same thickness (e.g., to with about 20%) as the inner backside layer. Hence, the outer backside layer is sometimes referred to a bulk backside layer or a second bulk layer.

The bow induced by the third, second, and first backside layers may be the sum of the individual induced bows. In some embodiments, bow magnitude of the combined backside layers may be about the same as the bow magnitude of the one or more frontside layers. In some embodiments, the bow contributions of all frontside and backside layers may combine so that the total bow of the wafer is minimal (i.e., less than 100 μm.) For example, the frontside layer(s) may induce a tensile bow of about 400 μm, while the first, inner, backside layer may induce a tensile bow of about 200 μm and the third, outer, backside layer may also induce a tensile bow of about 100 μm. The induced the crack arresting layer may be comparatively small or minimal.

Note that references to bow values induced or caused by individual backside layers assume that the bow is uncompensated by other layers. For example, when referring to the magnitude of a bow caused by a first backside layer, we assume that is the bow that would be produced on the substrate if no other layers were present, e.g., no frontside layers. The magnitude of a bow induced by a layer depends on both the internal stress of the material in the layer and the thickness of the layer.

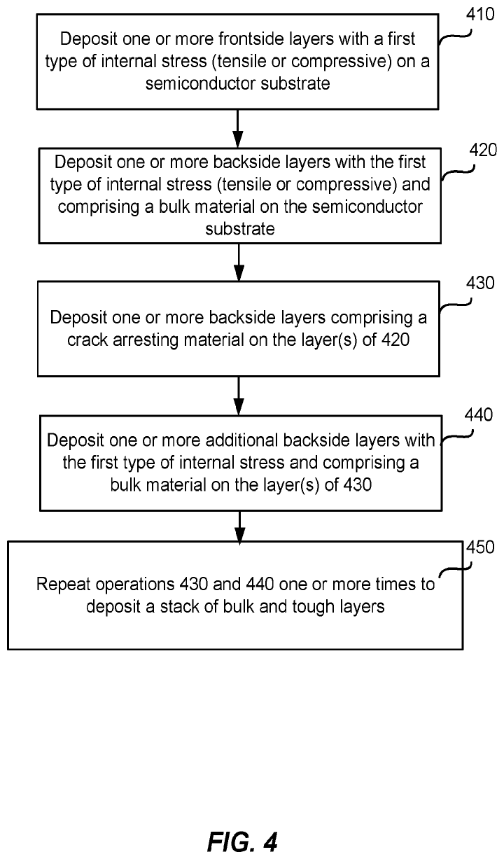

FIG. 4 shows a second example process of forming backside layer stack in a way that reduces the risk of cracking. The process of FIG. 4 begins by depositing one or more frontside layers with a first type of internal stress (tensile or compressive) on a wafer in an operation 410. The internal stress from the frontside layer causes the wafer to bow.

Once the frontside layer(s) are deposited onto the wafer, a first backside layer having the first type of internal stress onto the wafer in operation 420. The internal stress of the first backside layer counteracts the internal stress from the frontside layer and may help reduce wafer bow. This first backside layer may be a bulk layer. The first backside layer may be termed an inner backside layer.

In an operation 430, a second backside layer, which is a crack arresting layer, is deposited on the first backside layer. The second backside layer has an internal stress that may be neutral, the same as or opposite to the internal stress of the frontside layer and the first backside layer. As discussed above in the context of operation 630, the second backside layer may act reduce the likelihood that any backside layer will crack. The second backside layer may minimally reduce the bow induced by the frontside layer(s).

In an operation 440 a third backside layer, which may comprise a bulk material, is deposited onto the second backside layer. The third backside layer may have the first type of internal stress. In other words, the third backside layer has a stress that is the same as the stress of the frontside layer and the first backside layer. Like the first backside layer, the internal stress of the third backside layer counteracts the stress introduced from the frontside layer.

After the third backside layer is deposited, the process may be similar or identical that of FIG. 3. However, in the example of FIG. 4, the process repeats the deposition of the second, crack arresting, and third, bulk, backside layers as indicated in an operation 450. This effectively increases the number of layers in the stack. It may be appropriate when the bow induced by the front side layer(s) is so great that a single crack arresting layer may not be sufficient to avoid cracking. In some embodiments, the process cycles to deposit even more alternating layers of crack arresting and bulk layers. In other words, operation 450 is performed more than once.

The magnitude of the bow induced by each layer may be controlled to manage the overall bow of the substrate. For example, the magnitude of the stress from the sum of the deposited backside layers may be equivalent to the magnitude of the stress of the frontside layer(s). When the net difference in amount of bow from the frontside layers and the amount of bow from the deposited backside layers is relatively low, e.g., a difference of about 0 to 30%, the overall wafer bow may be minimal or acceptable for further processing.

In the backside deposition operations, 420-450, each of the deposition layers may be deposited by a backside deposition apparatus. In some embodiments, the wafer may stay in the same chamber for operations 420-450. In some embodiments, the wafer may switch chambers between operation 410 and operation 420. The backside deposition apparatus may be a different deposition apparatus then the apparatus used to deposit the one or more frontside layers. For example, the wafer may be in a first chamber for the deposition of the frontside layer in operation 410, and the wafer may be moved to a second chamber for the deposition of each backside layer in operations 420-450.

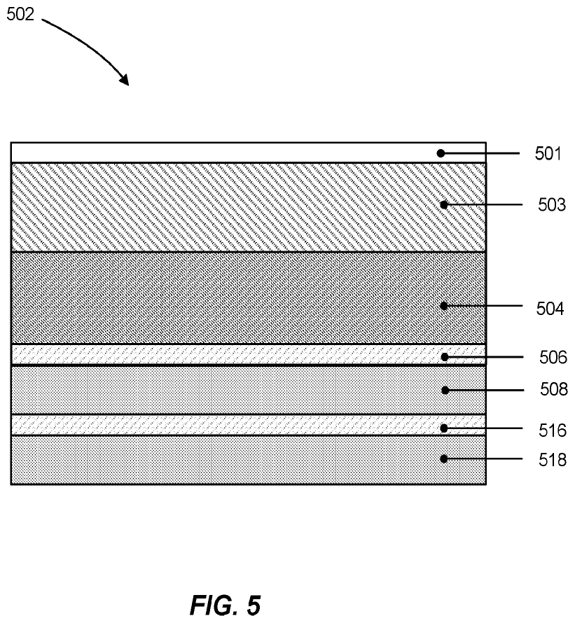

FIG. 5 shows an example cross section of a wafer 502 after undergoing the example process in FIG. 4. The wafer 502 has a main structure 503 (e.g., a single crystal silicon substrate). A frontside layer 501 is deposited on a frontside of the main structure 503. The frontside layer 501 has a first type of internal stress, which may be either a tensile or compressive internal stress. A first backside layer 504 is deposited on a backside of the main structure 503. The first backside layer 504 has the first type of internal stress, i.e., the same internal stress as the frontside layer. Layer 504 is a bulk backside layer. A second backside layer 506 is deposited on the first backside layer 506. The second backside layer 508 is a crack arresting layer. A third backside layer 508 is deposited on the second backside layer 506. The third backside layer 508 has the first type of internal stress. It is a second bulk layer (along with bulk layer 504).

A fourth backside layer 516 is deposited on the third backside layer 506. Backside layer 516 is composed of a crack arresting material. Hence, backside layer 516 may be considered a second crack arresting layer, along with layer 506.

Finally, a fifth backside layer 518 is deposited on the fourth backside layer 516. The fifth backside layer is composed of a bulk material and has the first internal stress type.

Collectively, the five backside layers on wafer 502 comprise a stack that includes three bulk layers 504, 508, and 518, interleaved with two crack arresting layers 506 and 516.

As discussed above, the internal stress of the frontside layer 501 may cause wafer bow. The internal stress of the backside layers may counteract the internal stress of the frontside layer 501. To minimize wafer bow, the net internal stress of the backside layers may be about equal to the internal stress of frontside layer 501. Thus, if the frontside layer 501 has a tensile bow with a magnitude of about 400 μm, the backside layers may have a sum tensile bow with a magnitude of about 400 μm.

### Bulk Layers

As explained, a backside layer stack may include one or more bulk layers and one or more crack arresting layers. The bulk layer(s) may provide most or substantially all the bow compensation, while the crack arresting layer provides relatively little, if any, bow compensation, while protecting against the bulk layers cracking. These functions or capabilities may result from different physical properties of the bulk layer(s) and the crack arresting layer(s). This section describes properties of the bulk layer(s).

Typically, in wafers having only a single backside layer, the backside layer thickness is approximately proportional to wafer bow. Greater wafer bow values require thicker backside compensating layers. Wafers with wafer bow of about 300 μm or greater, e.g., about 400 μm or greater, may require a backside film that is so thick that it may be susceptible to cracking. In a multilayer backside layer stack as disclosed herein, the total thickness of the bulk layers may, likewise be approximately proportional to wafer bow induced by one or more frontside layers. This assumes that the crack arresting layer (or layers) does not substantially contribute to bow compensation. While the total combined thickness of backside bulk layers typically depends on factors such as the amount of bow to be compensated and the intrinsic internal stress of the bulk layers, in some embodiments, the total thickness of all bulk layers (the sum of the thicknesses of all bulk layers on a wafer's backside stack) is at least 1 μm, or about 1 to 10 μm.

As with the total thickness of backside layers in a stack, the individual bulk layer thickness can vary depending on parameters such as the layer's intrinsic internal stress, the cracking margin of the bulk layer material, and the number of bulk layers in the backside stack. In many embodiments, each bulk layer is thicker than any crack arresting layer in the stack. In certain embodiments, the thickness of any individual backside layer within a stack is no greater than about 3 μm or about 0.1 to 3 μm. The recited thickness values may apply to any one or more bulk backside layers in a multilayer backside stack. Any two bulk backside layers may have the same or different thicknesses.

In certain embodiments, a bulk backside layer comprises a material having an intrinsic internal stress, which has a magnitude of at least about 100 MPa or about 100 to 1000 MPa. These values may be for tensile or compressive internal stress, as the case may be for the type of backside material needed to counteract bow caused by the frontside layer(s). In certain embodiments, the magnitude intrinsic internal stress of a bulk backside layer material is greater than that of a crack arresting layer in the backside stack. The above-recited internal stress values may apply to any one or more bulk backside layers in a multilayer backside stack. Any two bulk backside layers may have the same or different values of internal stress.

Example materials used to make bulk backside layers having tensile internal stress include silicon nitrides (SiN), silicon oxynitrides, and polymer layers. As examples, tensile films can be deposited using CVD or PECVD techniques. To combat wafer bow caused by a frontside layer with a compressive internal force, a compressive film may be used for the bulk backside layers. Compressive films may be formed using specific materials and/or processing conditions. Example materials used to make compressive films include silicon oxides (SiOₓ), silicon nitrides, aluminum oxides, aluminum nitrides, and polysilicon. Compressive films can be deposited using CVD or PECVD techniques. The above-recited materials and deposition techniques may apply to any one or more bulk backside layers in a multilayer backside stack. Any two bulk backside layers may be formed by the same or different techniques.

In certain embodiments, a bulk backside layer comprises a material having a density of about 1.5 to 3 g/cm³ or about 2.1 to 2.9g/cm³. In various embodiments, the bulk backside layer material is less dense than a crack arresting layer material in backside stack comprising the crack arresting layer and the bulk layer. The above-recited density characteristics may apply to any one or more bulk backside layers in a multilayer backside stack. Any two bulk backside layers may have the same or different densities.

### Crack Arresting Layer(s)

This section describes properties of the crack arresting layer(s) in accordance with certain embodiments.

The thickness of a crack arresting backside layer can vary depending on parameters such as the layer's intrinsic density, stiffness, and/or toughness. In many embodiments, a crack arresting backside layer is thinner than any bulk backside layer in a backside stack. In certain embodiments, the thickness of a crack arresting backside layer within a stack is no greater than about 2 μm or about 0.1 to 2 μm. In embodiments having multiple crack arresting backside layers, any two crack arresting backside layers may have the same or different thicknesses.

In certain embodiments, a crack arresting backside layer comprises a material having an intrinsic internal stress, which has a magnitude of at least about 500 MPa. Both tensile and compressive stress arresting layers may be used. In some bow applications, tensile stress can achieve higher bow compensation more easily. Examples, of internal stresses for a crack arresting backside layer can be about −500 MPA (compressive) to about 800 MPA (tensile). In embodiments having multiple crack arresting backside layers, any two crack arresting backside layers may have the same or different values of internal stress.

Examples of materials used for a crack arresting backside layer include silicon nitrides, silicon oxides, silicon oxynitrides, and any combination thereof. Other materials, including non-silicon-containing materials, can be used. In embodiments having multiple crack arresting backside layers, any two crack arresting backside layers may comprise the same or different materials.

In certain embodiments, a crack arresting backside layer comprises a material having a density of about 2 to 3.5 g/cm³ or about 2.3 to 3.1 g/cm³. In various embodiments, the crack arresting backside layer material is denser than a bulk layer material in backside stack comprising the crack arresting layer and the bulk layer. In embodiments having multiple crack arresting backside layers, any two crack arresting backside layers may have the same or different densities.

In certain embodiments, a crack arresting backside layer comprises a material having a fracture toughness that is greater than that of any bulk backside layer in the same stack with the crack arresting layer.

Fracture toughness is the critical stress intensity factor of a sharp crack where propagation of the crack suddenly becomes rapid and unlimited. Fracture toughness is a quantitative way of expressing a material's resistance to crack propagation and standard values for a given material are generally available.

In certain embodiments, a crack arresting layer has an elastic modulus of about 50 GPa to 250 GPa or about 180 GPa to 250 GPa.

A crack arresting backside layer may be deposited by any of the processes described herein for forming any backside layer, including a bulk backside layer. Those of skill in the art understand how to determine, tune, and/or adjust deposition conditions to produce a crack arresting backside layer having a composition, density, thickness, internal stress, toughness, and/or any other physical or chemical property as appropriate to provide suitable performance.

### Examples

By depositing a sandwich structure consisting of a relatively thin, dense, stiff, and high fracture toughness crack arresting film in between two bulk layers of a less dense, lower fracture toughness, the cracking margin of all films can be improved significantly. In one example, a sandwich stack structure demonstrated improvement in bow cracking limit of 12% to 46% compared to a single film. In other words, the bulk film by itself had bow cracking margin of X. With the multilayer stack, the stack structure was able to achieve bow cracking margin of 1.12× to 1.46×.

In one example, it was found that one backside bulk film had a cracking limit bow of 391 μm. Above this bow, the backside film must be too thick and will crack. However, it was found that when the bulk film was deposited in a film stack with a crack arresting layer, it was able to maintain no cracks up to 571 μm bow. This is an almost 50% improvement in bow cracking limit. This is because the inner film used in this stack acts as an arresting layer, separating the two layers above and below it, preventing any one layer from achieving a critical thickness, the critical bow limit. Therefore, a higher bow can be accepted without forming cracks in the backside layer.

### Apparatus

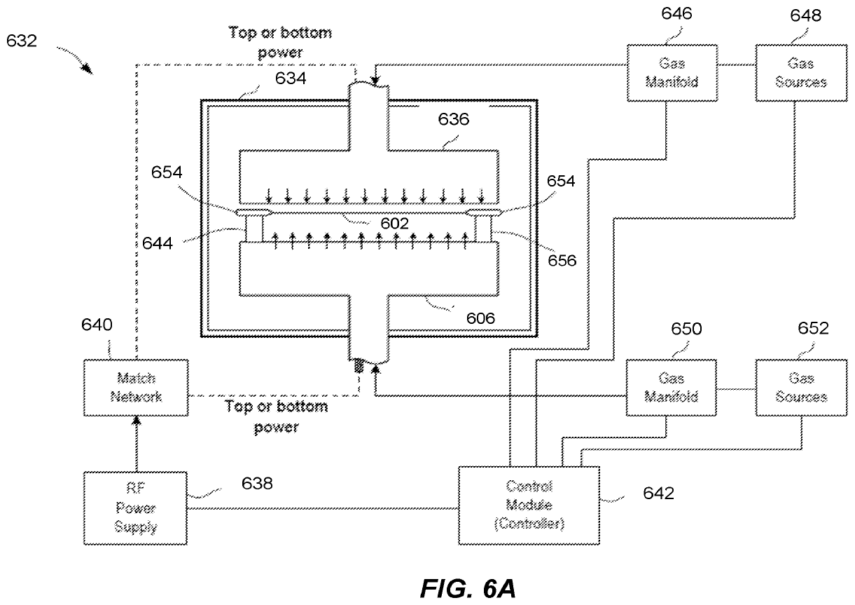

FIG. 6A is a block diagram that illustrates a substrate processing system 600 used to perform processing on a wafer 602 (also referred to as a wafer), according to some embodiments. As shown, the substrate processing system may include a chamber 634. A center column may be configured to support a pedestal for when a top surface of the wafer 602 is being processed, e.g., a film is being formed on the top surface of the wafer 602, or on the backside of the wafer 602. The pedestal, in accordance with some embodiments disclosed herein, may be referred to as a showerhead-pedestal (“ShoPed”) 606. A showerhead 636 may be disposed over the ShoPed 606.

In some embodiments, the showerhead 636 may be electrically coupled to power supply 638 via a match network 640. The power supply 638 may be controlled by a control module 642, e.g., a controller. In some embodiments, power may be provided to the ShoPed 606 instead of the showerhead 636. The control module 642 may be configured to operate the substrate processing system 632 by executing process input and control for specific process recipes. Depending on whether the top surface of the wafer 602 is receiving a deposited layer or layer stack or the bottom surface of the wafer 602 is receiving a deposited layer or layer stack, the controller module 642 may set various operational inputs for a process recipe, such as power levels, timing parameters, process gasses, mechanical movement of a wafer 602, and/or the height of the wafer 602 relative to the ShoPed 606.

In some embodiments, the center column may also include lift pins, which are controlled by a lift pin control. Such lift pins may be used to raise the wafer 602 from the ShoPed 606 to allow an end effector (not shown) to pick the wafer and to lower the wafer 602 after being placed by the end effector. The end effector may also place the wafer 602 over spacers 644. As will be described below, the spacers 644 may be sized to provide a controlled separation of the wafer 602 between a top surface of the showerhead 636 (facing the wafer) and a top surface of the ShoPed 606 (facing the wafer).

In some embodiments, the substrate processing system 632 may further include a first gas manifold 646 that is connected to first gas sources 648, e.g., gas chemistry supplies from a facility and/or inert gases. Depending on the processing being performed over a top surface of the wafer 602, the control module 642 may controls the delivery of first gas sources 648 via the first gas manifold 646. The chosen gases may then be flown into the showerhead 636 and distributed in a space volume defined between a face of the showerhead 636 that faces that wafer 602 when the wafer is resting over the pedestal.

In some embodiments, the substrate processing system 632 may further include a second gas manifold 650 that is connected to second gas sources 652, e.g., gas chemistry supplies from a facility and/or inert gases. Depending on the processing being performed over a bottom surface of the wafer 602, the control module 642 may control the delivery of second gas sources 652 via the second gas manifold 650. The chosen gases may then be flown into the showerhead 636 and distributed in a space volume defined between a face of the ShoPed 606 that faces an under surface or under side (e.g., backside) of the wafer 602 when the wafer is resting over the spacers 644. The spacers 644 may provide for a separation that optimizes deposition to the under surface of the wafer 602, while reducing deposition over the top surface of the wafer 602. In some embodiments, while deposition is targeted for the under surface of the wafer 602, an inert gas may be flown over the top surface of the wafer 602 via the showerhead 636, which may push reactant gases away from the top surface and enable reactant gases provided from the ShoPed 606 to be directed to the under surface of the wafer 602.

Further, the gases may be premixed or not. Appropriate valving and mass flow control mechanisms may be employed to ensure that the correct gases are delivered during the deposition and plasma treatment phases of the process. Process gases may exit the chamber 634 via an outlet. A vacuum pump (e.g., a one or two stage mechanical dry pump and/or a turbomolecular pump) may draw process gases out and maintains a suitably low pressure within the reactor by a close loop-controlled flow restriction device, such as a throttle valve or a pendulum valve.

In some embodiments, a carrier ring 654 may encircle an outer region of the ShoPed 606. When the top surface of the wafer 602 is being processed, e.g., a material is being deposited thereon, the carrier ring 654 may be configured to sit over a carrier ring support region that is a step down from a wafer support region in the center of the ShoPed 606. The top surface of the carrier ring 654 is generally coplanar with the top surface of the wafer 602. The carrier ring 654 may include an outer edge side of its disk structure, e.g., outer radius, and a wafer edge side of its disk structure, e.g., inner radius, that is closest to where the wafer 602 sits. The carrier ring 654 may be associated with an inner diameter (ID). The inner diameter may extend to an inner perimeter of the carrier ring and generally surround a substrate (e.g., wafer 602) in a processing chamber. The wafer edge side of the carrier ring 654 may also include a plurality of contact support structures or “tabs” which may be configured to lift the wafer 602 when the carrier ring 654 is held by the spacers 644. The carrier ring 654 may include a plurality of tabs with a quantity selected from a range to support the wafer 602 during processing. Additional details regarding embodiments of the tabs will follow.

FIG. 6B is a block diagram that illustrates another substrate processing system 632 used to perform processing on the wafer 602, according to some embodiments. In some embodiments, spider forks 656 may be used to lift and maintain the carrier ring 654 in its process height, e.g., to allow depositing in the under surface (backside) of the wafer 602. The carrier ring 654 may therefore be lifted along with the wafer 602. In some implementations, the carrier ring 654 may be rotated to another station, e.g., in a multi-station system.

Broadly speaking, the embodiments disclosed herein are for a system to deposit PECVD films on the selective side of the wafer (front and/or back) with dynamic control. Some embodiments may include a dual gas-flowing electrode for defining a capacitively-coupled PECVD system. The system may include a gas-flowing showerhead (e.g., showerhead 636) and a ShoPed 66. In some embodiments, the gas-flowing pedestal (i.e., ShoPed) is a combination showerhead and pedestal, which enables deposition on a back-side of the wafer. The electrode geometry combines features of a showerhead, e.g., a gas mixing plenum, holes, hole-pattern, gas jet preventing baffle, and features of a pedestal. Examples of features of a pedestal include an embedded controlled heater, wafer-lift mechanisms, ability to hold plasma suppression rings, and movability. This enables the transfer of wafers and the processing of gasses with or without RF power from the pedestal.

In some embodiments, the system may have a wafer lift mechanism that tightly controls parallelism of the substrates against the electrodes. In one example, this may be achieved by setting up the lift mechanism parallel to the two electrodes and controlling manufacturing tolerances, e.g., spindle or lift pins mechanisms. In another example, the lift may be achieved by raising the wafer lift parts. This option may not allow dynamic control of the side that gets deposited.

In some configurations, the lift mechanism may allow dynamically controlling the substrate position during processing (before plasma, during plasma, after plasma) to control the side of the deposition, profile of the deposition, and deposition film properties. The system may further allow selective enabling/disabling of the side where reactants are flown. One side can flow the reactant and the other side can flow inert gases to suppress the deposition and plasma.

In some embodiments, the gap between the side of the wafer that does not need plasma/dep may be tightly controlled. This distance may be controlled to suppress plasma. By not controlling the distance, the wafer may be susceptible to plasma damage. For example, the system may allow a minimal gap from about 2 mm to about 0.5 mm, and in another embodiment from about 1 mm to about 0.05 (limited by the wafer bow), and such gap can be controlled. The gap maybe controlled depending on process conditions.

In some embodiments, the gas-flowing pedestal (i.e., ShoPed) may enable, without limitation: (a) thermal stabilization of the wafer to processing temperature prior to processing; (b) selective design of hole patterns on the ShoPed to selectively deposition film in different areas of the back-side of the wafer; (c) swappable rings can be attached to achieve appropriate plasma confinement and hole pattern; (d) stable wafer transfer mechanisms within chamber and for transferring wafer outside to another chamber or cassette—such as lift pins, RF-coupling features, minimum-contact arrays; (e) implement gas mixing features, e.g., such as inner plenum, baffle and manifold lines openings; and (f) add compartments in the gas-flowing pedestal (i.e., ShoPed) to enable selective gas flow to different regions of the back side of the wafer and control flow rates via flow controllers and/or multiple plenums.

In another embodiment, dynamic gap control using wafer lift mechanism enables: (a) control of the distance from deposition or reactant flowing electrode to the side of the wafer that needs deposition or in the middle so that both sides can be deposited; and (b) the lift mechanism to control the distance dynamically during the process (before plasma, during plasma, after plasma) to control the side of the deposition, profile of the deposition, and deposition film properties. In another embodiment, for a deposition mode used to deposit on the backside of the wafer, film edge exclusion control is highly desirable to avoid lithography-related overlay problems. The lift mechanism used in this system is done via a carrier ring 654 that has a design feature to shadow the deposition on the edge. This specifies the edge exclusion control via the design and shape of the carrier ring.

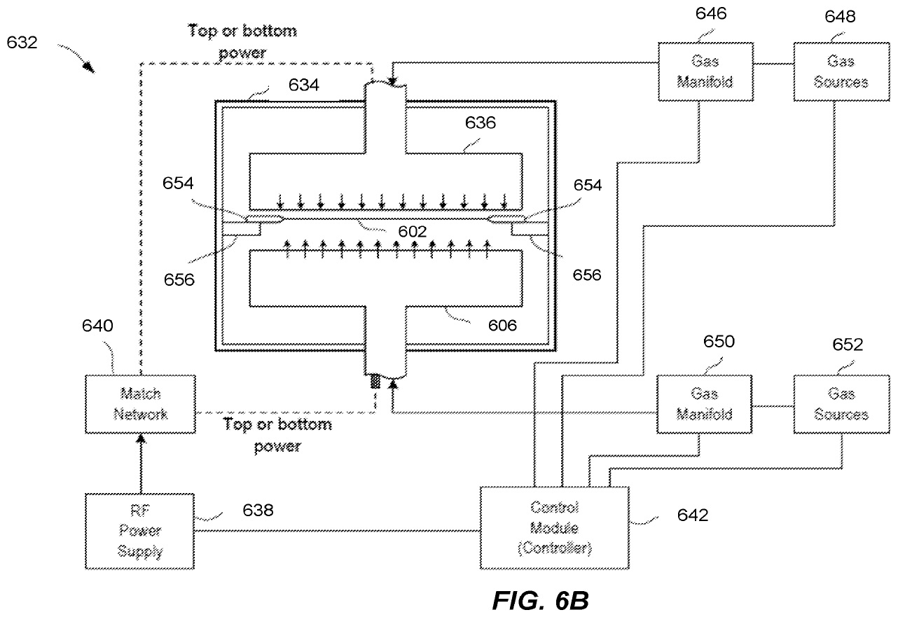

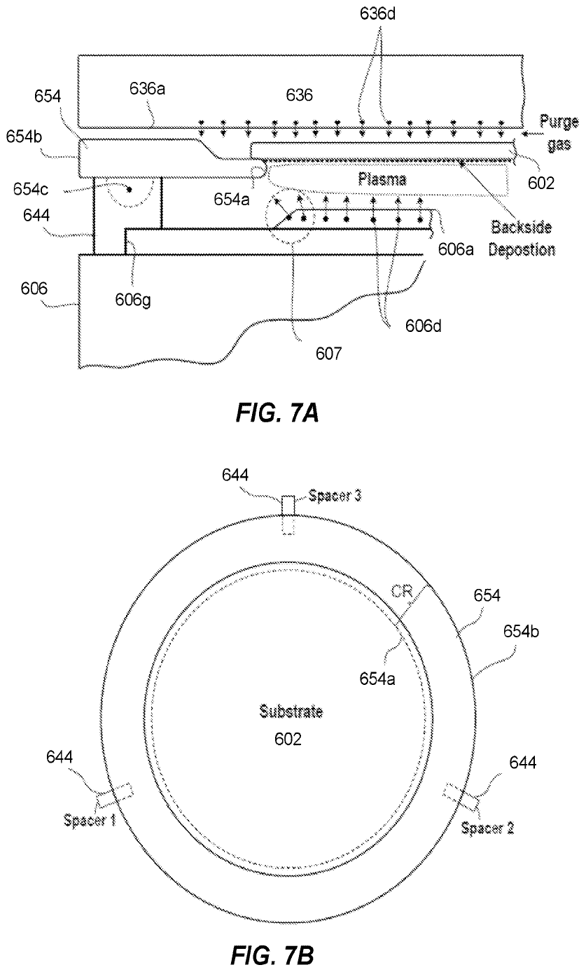

FIG. 7A shows a cross-sectional view of an edge region of the ShoPed 606. This view provides a cross-sectional representation of the carrier ring 654, which has a carrier ring inner radius 654a and a carrier ring outer radius 654b. In some embodiments, the carrier ring 654 includes support extensions 654c, which extend below the substantial flat surface of the carrier ring 654.

The support extensions 654c are configured to mate and sit within support surfaces defined into a top surface of the spacers 644. The support surfaces provide a complementary mating surface for the support extensions 654c, such that the carrier ring 654 is prevented from sliding or moving when supported by the spacers 644. Although three spacers are shown as spacers 644 are shown in FIG. 7B, it is envisioned that any number of spacers may be provided, so long as the carrier ring can be supported substantially parallel to the surface of the ShoPed 606, and spacing is defined for supporting wafer 602 at a spaced apart relationship from a top surface of the ShoPed 606.

Further shown is that a top surface of the ShoPed 606 will include a hole pattern 606a that is distributed throughout the surface to provide even distribution and output of gases during operation. In one embodiment, the hole pattern 606a is distributed in a plurality of concentric rings that start at the center of the top surface of the ShoPed 606 and extend to an outer periphery of the ShoPed 606. At least one hole pattern 606a is provided at an edge hole region 607 of the hole pattern, and orifices defined in the edge hole region 607 are preferably angled to provide gases non-perpendicular to the surface of the ShoPed 606.

In one example, the angle or tilt at which the orifices in the edge hole region 607 is defined to tilt or angle away from the center of the ShoPed 106. In one embodiment, the angle is approximately 45° from horizontal. In other embodiments, the angle can vary between 20° from horizontal to about 80° from horizontal. In one embodiment, by providing the angled orifices in the edge hole region 607, additional distribution of process gases can be provided during backside deposition of the wafer 602. In one embodiment, the remainder orifices 606d of the hole pattern 606a are oriented substantially perpendicular to the surface of the ShoPed 106 and directed toward the underside of the wafer 602.

FIG. 7B illustrates that when the wafer 602 is held by the carrier ring 654, the wafer 602 edge will sit on an edge region closer to the carrier ring inner radius 654a of the carrier ring 654. The surface of the showerhead 636 facing the top surface of the wafer 602, when positioned using spacers 644, may be substantially close to prevent deposition during a mode where deposition is being carried out to the backside of the wafer 602.

By way of example, the distance between the top of the wafer 602 and the surface of the showerhead 636 is preferably between about 2 mm to about 0.5 mm, and in some embodiments about 1 mm to about 0.5 mm, depending on the wafer bow. That is, if the wafer is bowed substantially, the separation will be about 0.5 mm or larger. If the wafer is not yet bowed substantially, the separation can be less than about 0.5 mm. In one embodiment, it is preferable that the separation be minimized to prevent deposition on the top side of the substrate when the backside of the substrate is being deposited with a layer of material. In some embodiments, the showerhead 636 is configured to supply an inert gas flow over the top side of the wafer 602 during when the backside of the substrate is being deposited and deposition gases are being supplied by the ShoPed 606.

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

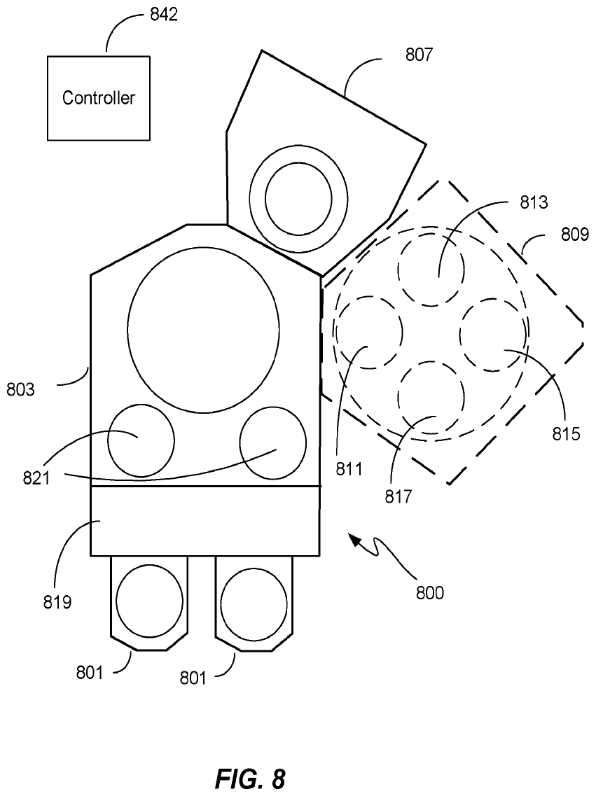

FIG. 8 is a schematic of a process system suitable for conducting deposition processes, such as frontside deposition processes, in accordance with embodiments. The system 800 includes a transfer module 803. The transfer module 803 provides a clean, pressurized environment to minimize risk of contamination of substrates being processed as they are moved between various reactor modules. Mounted on the transfer module 803 is a multi-station reactor 809 capable of performing ALD, treatment, and CVD according to various embodiments. Multi-station reactor 809 may include multiple stations 811, 813, 815, and 817 that may sequentially perform operations in accordance with disclosed embodiments. Stations may include a heated pedestal or substrate support, one or more gas inlets or showerhead or dispersion plate.

Mounted on the transfer module 803 may be one or more single or multi-station modules 807 capable of performing plasma or chemical (non-plasma) pre-cleans, other deposition operations, or etch operations. The module may also be used for various treatments to, for example, prepare a substrate for a deposition process. The system 800 also includes one or more wafer source modules 801, where wafers are stored before and after processing. An atmospheric robot (not shown) in the atmospheric transfer chamber 819 may first remove wafers from the wafer source modules 801 to loadlocks 821. A wafer transfer device (generally a robot arm unit) in the transfer module 803 moves the wafers from loadlocks 821 to and among the modules mounted on the transfer module 803.

In various embodiments, a system controller 842 is employed to control process conditions during deposition. The system controller 842 will typically include one or more memory devices and one or more processors. A processor may include a CPU or computer, analog and/or digital input/output connections, stepper motor controller boards, etc.

The system controller 842 may control all the activities of the deposition apparatus. The system controller 842 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the system controller 842 may be employed in some embodiments.

The depicted embodiment includes a user interface associated with the system controller 842. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 842. The signals for controlling the process are output on the analog and digital output connections of the system 800.

The system software may be designed or configured in different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a system controller 842 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 842, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

### System Controllers

Broadly speaking, a controller may be defined as electronics having various integrated circuits, logic, memory, and/or software that receive instructions, issue instructions, control operation, enable cleaning operations, enable endpoint measurements, and the like. Such controller may be used in or with any of the apparatus described herein. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

A system controller may be a part of or coupled to a computer that is integrated with, coupled to the system, otherwise networked to the system, or a combination thereof. For example, a system controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located

1. A method of processing a substrate during fabrication of an electronic device, the method comprising:
(a) depositing one or more frontside layers on a frontside of the substrate, wherein the one or more frontside layers induce a bow in the substrate;
(b) depositing a first backside layer on a backside of the substrate, wherein the first backside layer reduces the bow in the substrate;
(c) depositing a crack arresting backside layer over the first backside layer; and
(d) depositing a third backside layer over the crack arresting backside layer, wherein the third backside layer further reduces the bow in the substrate.

2. The method of claim 1, wherein the first backside layer, the crack arresting backside layer, and the third backside layer collectively comprise a backside stack, and wherein the backside stack has a thickness of about 2 to 15 μm.

3. The method of claim 1, wherein the first backside layer and the third backside layers each have thicknesses about 3 μm or less.

4. The method of claim 1, wherein the first backside layer comprises a silicon nitride.

5. The method of claim 1, wherein the first backside layer has an intrinsic internal stress magnitude of about 100 MPa to 1000 MPa.

6. The method of claim 1, wherein the crack arresting backside layer comprises a silicon nitride, a silicon oxide, a silicon oxynitride, or any combination thereof.

7. The method of claim 1, wherein the crack arresting backside layer has a density of about 2 to 3.5 g/cm.

8. The method of claim 1, wherein the crack arresting backside layer has a thickness of about 2 μm or less.

9. The method of claim 1, wherein the crack arresting backside layer has an elastic modulus of about 50 GPa to 250 GPa.

10. The method of claim 1, wherein the bow of the substrate is about 300 μm or more.

11. The method of claim 1, wherein at least one of the one or more frontside layers comprises a hardmask.

12. The method of claim 1, wherein the one or more frontside layers comprise a stack of about 100 or more alternating layers.

13. The method of claim 12, wherein the stack comprises alternating oxide layers and nitride or polysilicon layers.

14. The method of claim 1, wherein the one or more frontside layers has a first type of internal stress and wherein the first backside layer has the first type of internal stress.

15. An apparatus for semiconductor processing, the apparatus comprising:
a process chamber;
a substrate support within the process chamber;
a showerhead;
a gas source fluidically connected to the showerhead; and
a controller configured to cause:
(i) receiving a substrate comprising one or more frontside layers that cause bow in the substrate;
(ii) depositing a first backside layer on a backside of the substrate, wherein the first backside layer reduces bow in the substrate;
(iii) depositing a crack arresting backside layer over the first backside layer; and
(iv) depositing a third backside layer over the crack arresting backside layer, wherein the third backside layer further reduces the bow in the substrate.

16. The apparatus of claim 15, wherein the bow in the substrate is about 300 μm or more.

17. The apparatus of claim 15, wherein at least one of the one or more frontside layers is a hardmask.

18. The apparatus of claim 15, wherein the one or more frontside layers comprise a stack of about 100 or more alternating layers.

19. The apparatus of claim 15, wherein the first backside layer, the crack arresting backside layer, and the third backside layer collectively comprise a backside stack, and wherein the backside stack has a thickness of about 2 to 15 μm.

20. The apparatus of claim 15, wherein the first backside layer and the third backside layers each have thicknesses about 3 μm or less.

21. The apparatus of claim 15, wherein the first backside layer comprises a silicon nitride.

22. The apparatus of claim 15, wherein the first backside layer has an intrinsic internal stress of about- 500 MPa to 500 MPa.

23. The apparatus of claim 15, wherein the crack arresting backside layer has a density of about 2 to 3.5 g/cm.

24. The apparatus of claim 15, wherein the crack arresting backside layer has a thickness of about 2 μm or less.

25. The apparatus of claim 15, wherein the crack arresting backside layer has an elastic modulus of about 50 GPa to 250 GPa.

26. The apparatus of claim 15, wherein the crack arresting backside layer comprises a silicon nitride, a silicon oxide, a silicon oxynitride, or any combination thereof.
